(19) United States
(12) Patent Application Publication
(10) Pub. No.: US 2014/0327456 A1
(43) Pub. Date: Nov. 6, 2014

(54) DETECTING CIRCUIT FOR FAN INSTALLATION

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: KANG WU, Shenzhen (CN); BO TIAN, Shenzhen (CN)

(73) Assignees: HONG FU JIN PRECISION INDUSTRY (ShenZhen) CO., LTD, Shenzhen (CN); HON HAI PRECISION INDUSTRY CO., LTD., New Taipei (TW)

(21) Appl. No.: 14/264,480

(22) Filed: Apr. 29, 2014

(30) Foreign Application Priority Data
May 2, 2013 (CN) 2013101583224

(51) Int. Cl. G01R 27/02

(52) U.S. Cl. CPC G01R 27/02
USPC 324/691

(57) ABSTRACT

Detecting circuit for a plurality fans includes a plurality of detecting units, a connection unit, a processing unit, and a plurality of indicating units whose number equals the number of the detecting units. The detecting units detect whether the fans have been properly installed and then output detection signals. The connection unit transfers the detection signals to the processing unit. The processing unit processes the detection signals and outputs judgment signals. The indicating units indicate installation states of the fans according to the judgment signals.

### FIELD

The present disclosure relates to a detecting circuit for fans installation of a server.

### BACKGROUND

An electronic device, such as a server can use fans to cool off.

### BRIEF DESCRIPTION OF THE DRAWING

Many aspects of the embodiments can be better understood with reference to the following drawings. The components in the drawings are not necessarily drawn to scale, the emphasis instead being placed upon clearly illustrating the principles of the presented embodiments. Moreover, in the drawings, like reference numerals designate corresponding parts throughout the several views.

FIG. 1 is a block diagram of an embodiment of a detecting circuit.

FIG. 2 and FIG. 3 are circuit diagrams of an embodiment of a detecting circuit.

### DETAILED DESCRIPTION

The disclosure, including the figures, is illustrated by way of example and not by way of limitation. References to “an” or “one” embodiment in this disclosure are not necessarily to the same embodiment, and such references mean “at least one”. Although discussion herein is directed to a server, it will be understood the principles described can be utilized with other e-devices.

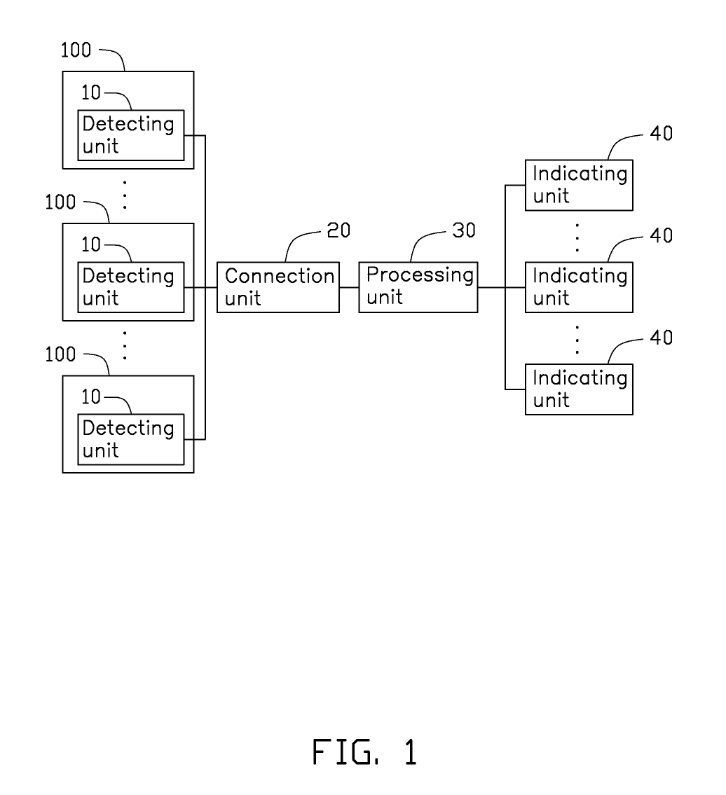

FIG. 1 illustrates an embodiment of a detecting circuit for detecting and indicating installation states of fans in a server. In the embodiment, the detecting circuit can comprise a plurality of detecting units 10, a connection unit 20, a processing unit 30, and a plurality of indicating units 40 whose number corresponds to the number of the detecting units 10.

In at least one embodiment, each of the detecting units 10 is located on a bottom of a fan mounting groove 100 in the server, for detecting whether the fans are installed in the fan mounting grooves 100 and outputting detecting signals. The connection unit 20 is connected to the detecting units 10 for receiving the detecting signals and outputting the detecting signals. The processing unit 30 is connected to the connection unit 20 for receiving the detecting signals and outputting judgment signals according to the detecting signals. The indicating units 40 are connected to the processing unit 30 for receiving the judgment signals and indicate the installation states of the fans.

In at least one embodiment, the number of the detecting units 10 is six, and accordingly, the number of the indicating units 40 is six.

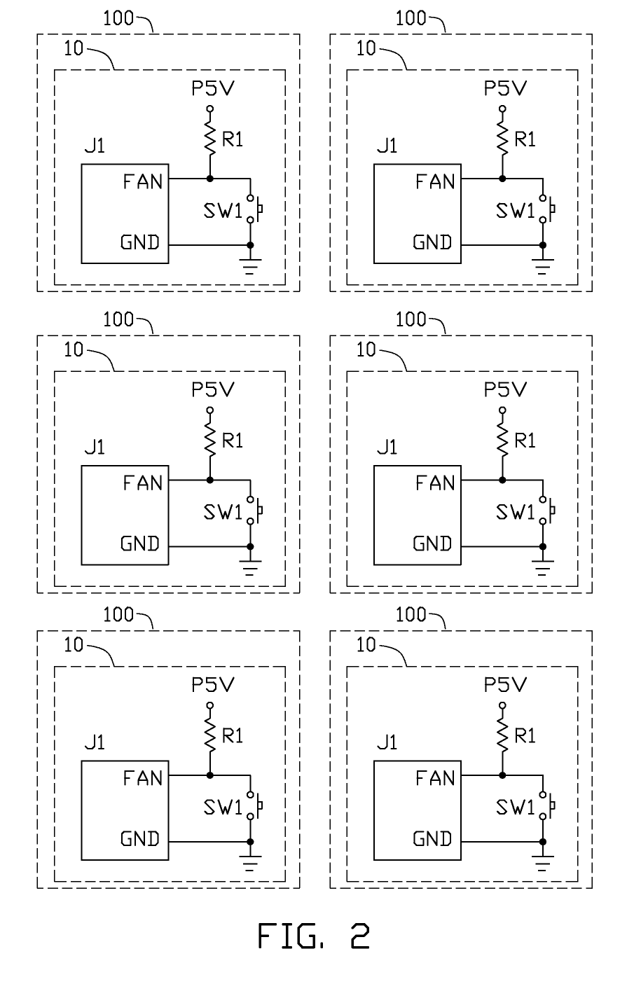

FIG. 2 illustrates the six detecting units 10 located on the bottom of fan mounting grooves 100 of the detecting circuit. Each of the detecting units 10 can comprise a switch SW1, a resistor R1, and a connector J1. A first terminal of the switch SW1 is connected to a power source P5V through the resistor R1. The first terminal of the switch SW1 is connected to a signal pin FAN of the connector J1. A second terminal of the switch SW1 is connected to a grounded pin GND of the connector J1 and grounded.

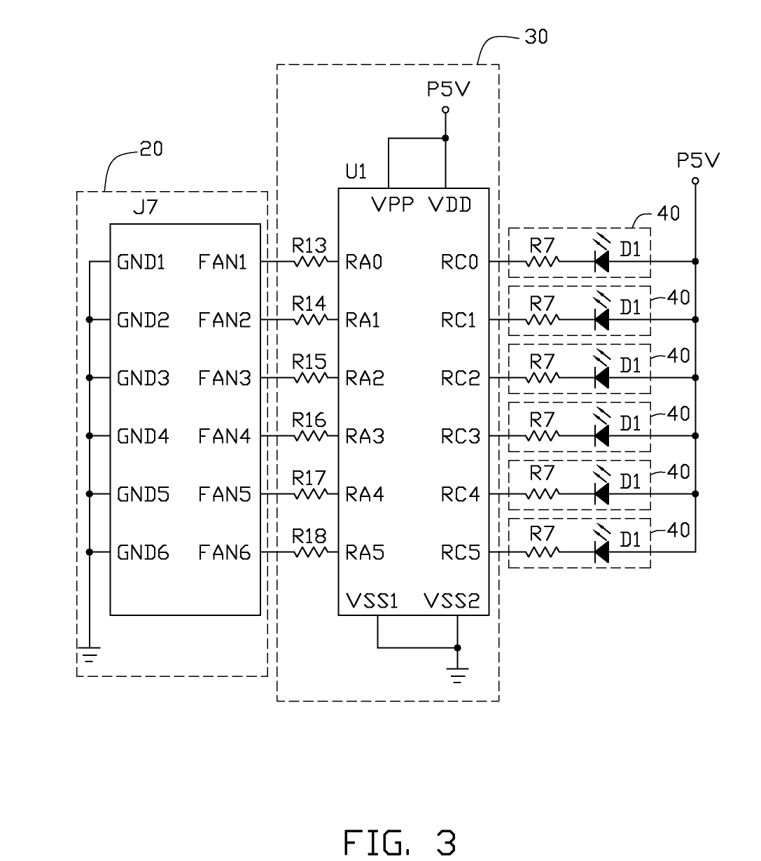

FIG. 3 illustrates the connection unit 20, the processing unit 30, and the six indicating units 40 of the detecting circuit. The connection unit 20 comprises a connector J7. The connector J7 comprises output pins FAN1-FANG connected to the signal pins FAN of each of the connectors J1 and grounded pins GND1-GND6 connected to a ground. The processing unit 30 comprises a single-chip U1 and resistors R13-R18. The single-chip U1 comprises input pins RA0-RA5 connected to the output pins FAN1-FAN6 of the connector J7 through the resistors R13-R18 respectively, power pins VDD and VPP connected to the power source P5V, ground pins VSS1 and VSS2 connect to a ground, and output pins RC0-RC5 connected to the indicating units 40 respectively. Each of the indicating units 40 comprises a resistor R7 and a light emitting diode (LED) D1. Cathodes of the LEDs D1 are connected to the output pins RC0-RC5 of the single-chip U1 through the resistor R7 respectively. Anodes of the LEDs D1 are connected to the power source P5V.

When the first fan is installed in first fan mounting groove 100 properly, the switch SW1 in the first fan mounting groove 100 is pressed by the first fan and is thereby turned on. The signal pin FAN of the connector J1 in the first fan mounting groove 100 is connected to a ground through the switch SW1. The output pin FAN1 of the connector J7, which is connected to the signal pin FAN, outputs a low-level signal, such as logic 0, to the input pin RA0 of the single-chip U1. Since the input pin RA0 of the single-chip U1 received a low-level signal, the output pin RC0 of the single-chip U1 does not output a corresponding signal, and the LED D1 of the first indicating unit 40 cannot be lit, which indicates the first fan is installed in the first fan mounting groove 100 properly.

When the first fan installed in the first fan mounting groove 100 is not installed properly in position, the switch SW1 in the first fan mounting groove 100 is not pressed by the first fan and is thereby turned off. The signal pin FAN of the connector J1 is connected to the power source P5V through the resistor R1. The output pin FAN1 of the connector J7, which is connected to the signal pin FAN, outputs a high-level signal, such as logic 1, to the input pin RA0 of the single-chip U1. Since the input pin RA0 of the single-chip U1 received a high-level signal, the output pin RC0 of the single-chip U1 outputs a low-level signal corresponding, and the LED D1 of the first indicating unit 40 is lit, which indicates the first fan installed in the first fan mounting groove 100 is not installed properly in position.

As detailed above, the connector J7 connected with the fan mounting grooves 100 outputs the detecting signals to the single-chip U1. The single-chip U1 controls the LEDs D1 to be lit or not, to indicate the fan installation state according to the detecting signals received.

Even though numerous characteristics and advantages of the disclosure have been set forth in the foregoing description, together with details of the structure and function of the disclosure, the disclosure is illustrative only, and changes can be made in detail given, including matters of shape, size, and arrangement of parts within the principles of the disclosure to the full extent indicated by the broad general meaning of the terms in which the appended claims are expressed.

What is claimed is:

1. A detecting circuit for detecting and indicating an installation state of a fan, comprising:
a detecting unit, located on a fan mounting groove for detecting whether the fan is installed in the fan mounting groove and outputting a detecting signal;
a connection unit connected to the detecting unit for receiving the detecting signal and outputting the detecting signal;
a processing unit connected to the connection unit for receiving the detecting signal and outputting a judgment signal corresponding to the detecting signal; and
an indicating unit connected to the processing unit for receiving the judgment signal and indicating the installation state of the fan.

2. The detecting circuit of claim 1, wherein the detecting unit comprises a switch, a first resistor, and a first connector, a first terminal of the switch is connected to a power source through the first resistor, the first terminal of the switch is connected to a signal pin of the first connector, a second terminal of the switch is connected to a grounded pin of the first connector and the second terminal of the switch is connected to a ground.

3. The detecting circuit of claim 2, wherein the connection unit comprises a second connector, the second connector comprises an output pin and a ground pin, the output pins are connected to the signal pin of the first connector, the ground pin is connected to a ground.

4. The detecting circuit of claim 3, wherein the processing unit comprises a single-chip and a second resistor, the single-chip comprises a input pin connected to the output pin of the second connector through the second resistor, a power pin connected to the power source, a ground pin connected to a ground, and an output pin connected to the indicating unit.

5. The detecting circuit of claim 3, wherein the indicating unit comprises a third resistor and a light emitting diode (LED), wherein a cathode of the LED is connected to the output pin of the single-chip through the third resistor, and an anode of the LED is connected to the power source.
